(19) United States
(12) Patent Application Publication
(10) Pub. No.: US 2002/0005765 A1
(43) Pub. Date: Jan. 17, 2002

(54) Digital indirectly compensated crystal oscillators

(76) Inventors: William Ashley, Carlsbad, CA (US); Lothar Baum, Vista, CA (US); Samir Kuliev, San Diego, CA (US)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/809,948

(22) Filed: Mar. 16, 2001

Related U.S. Application Data
(60) Provisional application No. 60/190,270, filed on Mar. 17, 2000.

(51) Int. Cl. H03L 1/02

(52) U.S. Cl. 331/176; 331/158

(57) ABSTRACT

A method and system for compensating for thermally-based frequency fluctuations of a piezoelectric crystal. A characterization of the frequency-temperature response of the crystal is stored in a memory. During operation, a host system is provided with the crystal's uncompensated frequency, the temperature of the crystal, and frequency correction values stored in the memory. The host system may then determine a compensated frequency by retrieving, or deriving through interpolation, a frequency correction value from the data provided in the memory.

### RELATED APPLICATION

This application claims priority to, and hereby incorporates by reference in its entirety, U.S. Provisional Patent Application No. 60/190,270 filed Mar. 17, 2000.

### BACKGROUND OF THE INVENTION

1. Field of the Invention

This invention relates to crystal oscillators. More particularly, the invention relates to digital indirectly compensated crystal oscillators.

2. Description of the Related Art

The individual components in certain airborne navigation and landing systems, such as global positioning systems, are usually equipped with clock generators that provide time control of the internal operations or procedures of system components. To achieve frequency synchronism between the individual system components, clock information generated by a central, high-precision clock device is communicated to the system components and is used for synchronization of the clock generators. Such frequency synchronization devices are known as phase frequency control circuits, or phase locked loop (PLL) devices. A PLL device typically includes a voltage-controlled oscillator (VCO) and a phase comparator with a following filter. The comparator compares phases of the output signal of the VCO to the clock information and controls the VCO depending on the result of the comparison. The VCO typically comprises a piezoelectric crystal that is used to provide a stable output frequency.

As is well known, piezoelectric crystals derive functionality from the fact that they deform slightly in the presence of an electric field. Generally, however, the operating frequency of a piezoelectric crystal varies as a function of temperature. Hence, changes in ambient temperature cause temperature fluctuations in the crystal, which in turn produce deviations in the output frequency of the crystal. The frequency deviations follow temperature response curves that can be determined for each unique crystal. This is commonly known as the frequency-temperature (FT) response of the crystal. FIG. 1 shows the Bechmann curve for a typical quartz crystal. The FT response of a crystal is partly determined by the type of crystal section, i.e., the angle relative to a crystal axis, at which the crystal is cut from a source quartz crystal. Many current radiotelephones, for example, use a so-called “AT-cut” crystal for the crystal oscillator. In general, the AT-cut crystal has the most stable frequency over temperature.

Because the FT response of a crystal is generally an undesirable effect, a temperature compensating apparatus is normally used to stabilize the crystal's frequency output. Two basic techniques are commonly used to accomplish this. One technique involves enclosing the crystal within an oven to maintain the crystal at a constant temperature and thereby keep its frequency output stable. A crystal oscillator compensated in this manner is known as an oven controlled crystal oscillator (OCXO). The second technique involves applying a temperature varying voltage across a voltage variable capacitor, which controls the resonant frequency of the crystal. When the temperature-varying voltage is properly derived, the voltage variable capacitor tunes the crystal in such a manner as to maintain its actual frequency output near the desired frequency output over the required temperature range. A crystal oscillator controlled in such a manner is called a temperature compensated crystal oscillator (TCXO).

FIG. 1B is a functional block diagram of an OCXO well known in the relevant technology. The crystal 112 in an OCXO is typically enclosed in an oven-like structure 114 that is heated by a heating device to maintain the temperature of the crystal 112 at a predetermined temperature, which is usually the temperature at which the crystal's 112 resonant frequency is most stable. A temperature sensing mechanism 118 is frequently used in a closed loop feedback system to control the amount of heat input to the oven in order to keep the temperature and, hence, the frequency of the crystal 112 stable over time. Typically, OCXOs are provided with separate fixed or variable components for both tuning the crystal oscillator to a desired frequency, and setting the oven at a desired temperature. Thus, the purpose of an OCXO is to minimize frequency change over temperature by maintaining the crystal within a stable thermal environment. An OCXO, however, requires a large volume of space and consumes substantial amounts of power.

The most popular crystals for OCXO applications are AT- and SC-cut quartz crystals, which are well known in the relevant technology. The SC-cut crystal is generally unsuitable for use in TCXO designs because it is difficult to tune; however, it works very well in OCXO applications. Because the SC-cut crystal has lower noise characteristics relative to a comparable AT-cut crystal, applications that require low noise levels typically use the SC-cut crystal; however, such designs incur the costs associated with the larger size and power requirements of the OCXO design required to stabilize the SC-cut crystal.

For many quartz crystals, the temperature at which the quartz must be kept to stabilize its frequency is relatively high. A SC-cut crystal, for example, is known to have a very stable output frequency near 80° C. Unfortunately, maintaining such a high temperature in an ovenized environment consumes large amounts of power; additionally, the relatively high temperature results in a long temperature settling time (i.e., the time it takes for the temperature inside the oven to stabilize). Moreover, other temperature-sensitive semiconductor components located close to the oven might require thermal isolation from the oven to protect them from the heat transferred from the OCXO that can adversely affect their performance. Another problem frequently encountered with OCXOs is that the persistent high temperature of the crystal causes premature performance degradation. The higher temperature decreases the mean time between failures (MTBF) of the device, and degrades aging performance. This premature performance degradation increases the maintenance costs of systems having OCXOs.

FIG. 1C is a functional block diagram of a TCXO 140 well known in the relevant technology. TCXOs are commonly found in electric communication devices, such as cellular phones and wireless radios, which require stable operating frequencies and low power consumption. Unlike OCXO designs, a TCXO 140 application does not attempt to maintain a stable thermal environment for the crystal 142. In a TCXO 140, compensation for frequency deviations of the crystal 142 is accomplished by varying the voltage 144 applied to the voltage variable capacitance 150 regulating the crystal 142, rather than maintaining the crystal 142 at a nearly constant temperature. TCXOs are known to include analog and digital types, each utilizing several components. A typical analog TCXO includes a piezoelectric element, capacitors, inductors, resistors, etc. A typical digital temperature-compensated crystal oscillator (DTCXO) includes a piezoelectric element, an integrated circuit, and capacitors.

In analog TCXO applications, usually the crystal is thermally coupled to a temperature sensor 146 of a temperature measuring device which creates an analog voltage that is directly applied to a tuning device 148, e.g., the voltage control input of the oscillator 142. In DTCXO applications, the analog voltage output of the temperature sensor may be digitized and supplied to a memory. The memory stores in digital form the voltage values required for compensation at the measured temperature. Each digitized measured temperature value has a digital compensation voltage value assigned thereto. After a digital to analog conversion, the voltage compensation value is fed to the voltage control input of the crystal as an analog compensation voltage and effects a correction of the temperature-conditioned frequency deviations.

Generally, TCXOs are used to provide a frequency that is stable to within five parts per million (5 ppm) or less. Higher stability requires more complexity in a TCXO design. Analog circuits become ungainly in high stability oscillators because they require additional components. Consequently, digital temperature compensated crystal oscillators (DTCXOs), which incorporate complex integrated circuitry, are being used increasingly in applications requiring 2 ppm stability or better. An example of such a DTCXO is described in U.S. Pat. No. 5,691,671, issued to Bushman, entitled “Method and Apparatus for a Crystal Oscillator using Piecewise Linear Odd Symmetry Temperature Compensation,” and which is incorporated by reference herein in its entirety. Typically, the DTCXO includes a memory containing predetermined voltage correction values that are complementary to a FT response curve (i.e., a Bechmann curve as shown in FIG. 1) of a pretested crystal. Due to the digital nature of the compensation, a preset correction voltage is applied within a discrete, fixed temperature segment. Generally, each of these correction values is applied through a digital-to-analog conversion to a tuning circuit of the crystal so as to return the frequency of the crystal to a nominal value within that temperature segment.

In this solution, an integrated circuit continuously monitors the temperature in the vicinity of the crystal. The integrated circuit then applies a new voltage correction value for every five degree (5° C.) temperature segment, for example. This compensation process, however, produces a discontinuous frequency performance. That is, as the temperature fluctuates the digital-to-analog conversion output will change values in discrete steps, which then causes steps in the output frequency of the DTCXO. These abrupt frequency jumps may disrupt desired communication signals or interfere with other neighboring frequency signals. Although smaller temperature segments may be used to improve frequency stability, memory and circuit size limitations have constrained known DTCXOs to utilizing temperature segments of constant and minimum width.

In view of the above discussion of OCXO, TCXO, and DTCXO designs, it is apparent that there is a need in the relevant technology for a system that compensates for the FT response of a crystal oscillator while overcoming the disadvantages of the known designs. Such a compensation system should avoid the use of a compensation apparatus that applies an input to the crystal oscillator in order to modify its output and produce a compensated frequency. Such a system should also reduce the stepped frequency output associated with the DTCXO design, without increasing the complexity, size, and costs of the required circuitry. What is needed is a system that takes advantage of the superior noise characteristics of a design having an SC-cut crystal, as well as the low power consumption and compactness of a DTCXO design, while avoiding the bulkiness and large power requirements of the OCXO design.

### SUMMARY OF THE INVENTION

The system and method of the present invention have several aspects, no single one of which is solely responsible for the desirable attributes of the invention. Without limiting the scope of this invention as expressed by the claims, features of the system and method will now be discussed briefly.

In one embodiment the invention is a system for providing a frequency correction value associated with thermally-based frequency deviations of a crystal. Such a system includes a crystal for producing an uncompensated frequency output, a thermal sensor which provides a signal reflective of the temperature of the crystal, a memory which stores data characterizing the frequency-versus-temperature responses of the crystal, and a device, responsive to the signal from the thermal sensor and the data stored in the memory, for providing a frequency correction value associated with the uncompensated frequency output of the crystal.

Another embodiment of the invention is an apparatus for compensating for thermally based frequency variations in an output of a piezoelectric crystal. The apparatus includes a thermal sensor which provides an output representative of the temperature of the crystal, a memory which stores a plurality of frequency correction values, wherein the plurality of correction values are associated with frequency-temperature responses of the crystal, a device responsive to the output of the thermal sensor for selecting at least one frequency correction value from the memory which correlates with said output. In such an apparatus the device, in response to the output of the crystal and the selected at least one frequency correction value, provides an output comprising a modification of the output of the crystal.

In yet another embodiment, the invention comprises of an apparatus for compensating for thermally based frequency variations in an uncompensated output signal associated with a piezoelectric crystal. The apparatus includes a temperature sensor which identifies a temperature representative of the temperature of the crystal, a memory which stores frequency correction values associated with the temperature of the crystal, an application which accesses the memory and retrieves at least one frequency correction value associated with the identified temperature, and at least one output which provides the uncompensated output signal and the at least one retrieved frequency correction value to a device such that the operation of the device is influenced by the uncompensated output signal and the frequency correction value.

In another embodiment, the invention is a method of compensating for thermally based frequency variations in an output signal associated with a piezoelectric crystal. The method includes the acts of identifying a temperature representative of the temperature of the crystal, producing a frequency correction value in response to the identified temperature, and providing the output signal and the frequency correction value to a system such that a component of the system functions in a manner which is influenced by the frequency correction value.

In yet another embodiment, the invention is a method of compensating for variations in output from a piezoelectric crystal which is provided to a host system. Such a method involves identifying output characteristics of the crystal in selected operating conditions, and modifying an output of the crystal, independent from influencing operation of the crystal, using at least one of the identified output characteristics to compensate for the influence of selected operating conditions on said output.

### BRIEF DESCRIPTION OF THE DRAWINGS

The foregoing summary, as well as the following detailed description of the preferred embodiments, is better understood when read in conjunction with the appended drawings. For the purpose of illustrating the invention, there is shown in the drawings an embodiment that is presently preferred, it being understood, however, that the invention is not limited to the specific methods and instrumentalities disclosed.

FIG. 1 shows a FT response curve for a typical AT-cut quartz crystal.

FIG. 1B is a functional block diagram of an OCXO well known in the relevant technology.

FIG. 1C is a functional block diagram of a TCXO well known in the relevant technology.

FIG. 2A is a block diagram of a digital indirectly compensated crystal oscillator (DICXO) according to the present invention.

FIG. 2B is a functional block diagram of one embodiment of a system for frequency compensation using the DICXO of FIG. 2A.

FIG. 3 shows an exemplary look-up table having frequency correction values associated with temperature values in the temperature range of operation of the DICXO of FIG. 2A.

FIG. 4 shows a FT response curve for a SC-cut crystal used to determine the frequency correction versus temperature values of the look-up table of FIG. 3.

FIG. 5 shows a complete hysteresis curve and a best-fit curve for the SC-cut crystal of FIG. 4.

FIG. 6 shows an exemplary look-up table that may be used in conjunction with an ADC which may be included with the DICXO of FIG. 2A.

FIG. 7 is a flowchart illustrating a process of frequency compensation using the DICXO of FIG. 2A.

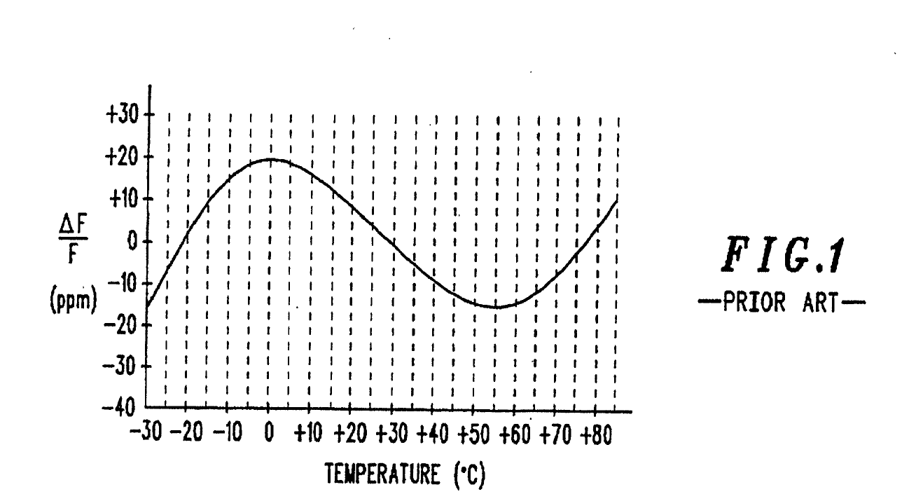

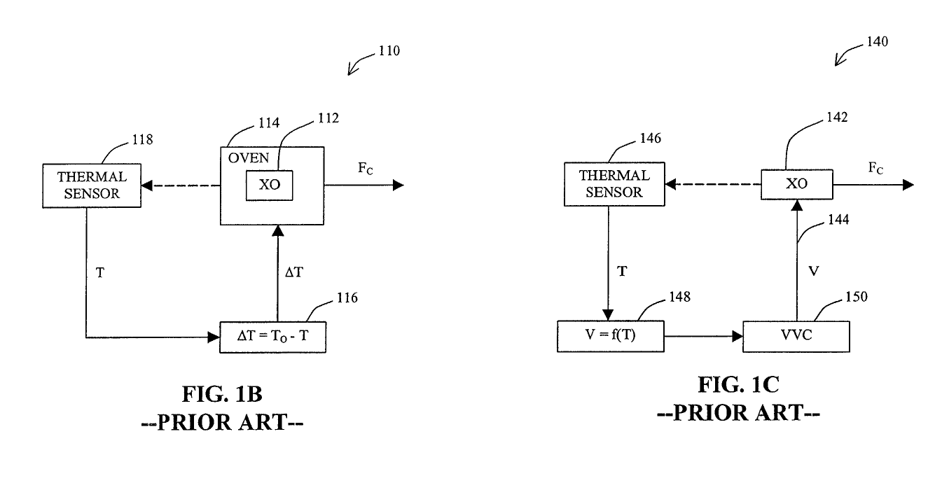

### DETAILED DESCRIPTION OF THE PREFERRED EMBODIMENT

The following detailed description is directed to certain specific embodiments of the invention. However, the invention can be embodied in a multitude of different ways as defined and covered by the claims. In this description, reference is made to the drawings wherein like parts are designated with like numerals throughout.

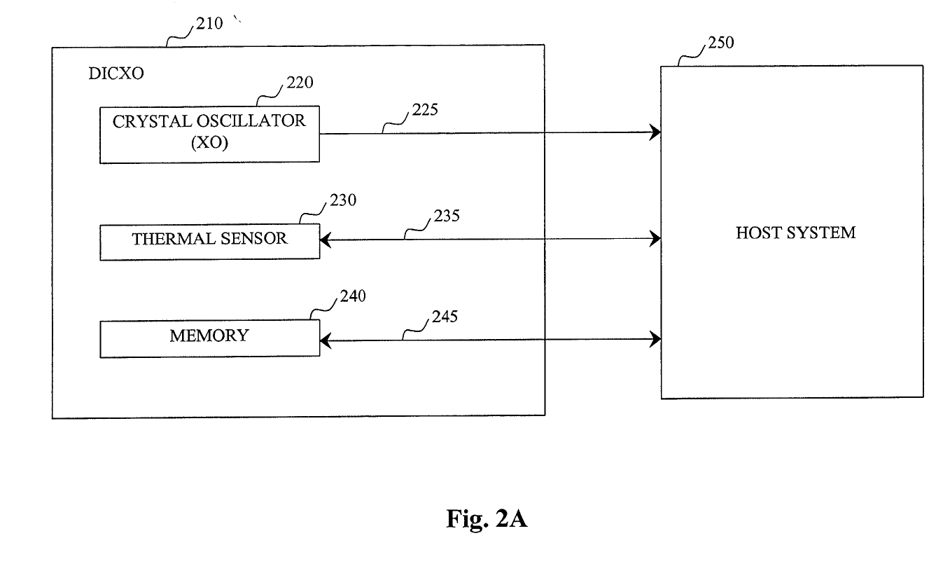

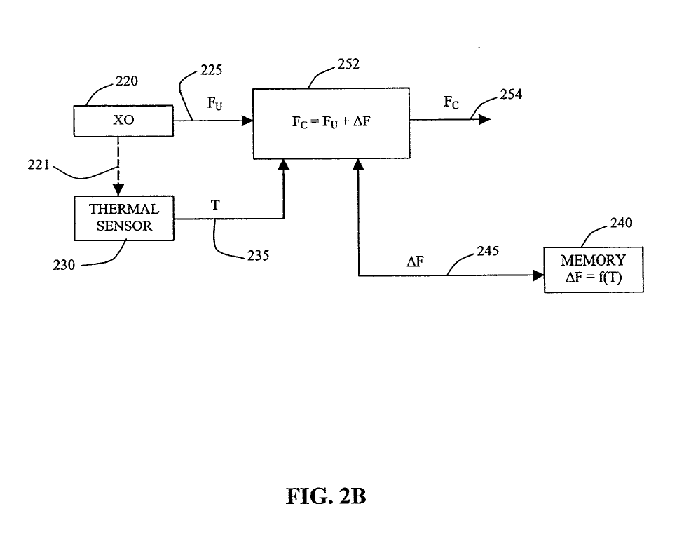

FIG. 2A is a block diagram showing one embodiment of a digital indirectly compensated crystal oscillator (DICXO) 210 according to the invention. The DICXO 210 is a high-precision clock device, having a non-temperature compensated crystal oscillator (XO) 220, that provides the host system 250 with the necessary data to compensate for the FT response of the uncompensated XO 220. The DICXO 210 thus enables the host system 250 to, for example, maintain the synchronization of the clock generators of its individual components. The individual components of the host system 250 are not shown in FIG. 2.

In one embodiment, the host system 250 may be, for example, a global positioning system used in airborne navigation and landing equipment; however, a DICXO 210 according to the invention may be used in, or in conjunction with, any system having digital processing capabilities and which can operate using an uncompensated reference frequency and a corresponding frequency correction value. Applications that may use the DICXO 210 include radar and ranging equipment, frequency and time measuring devices, precision time references, synthesizers, and most circuits that use numerically controlled oscillators (NCOs) well known in the relevant technology. For example, in a radar system, the DICXO 210 may be used to minimize the apparent Doppler shift caused by the temperature-induced frequency deviations of the XO 220. The DICXO 210 enables NCOs to add in a correction term that compensates for the frequency shift of XO 220 by providing a frequency correction value. In one such application, the NCO uses the frequency correction value to accelerate the NCO cycle time by the amount required to compensate for the frequency deviation of the XO 220 from its nominal frequency. In this manner the NCO offsets the frequency output 225 of the XO 220 to restore the output frequency of the NCO to near its ideal output frequency. In yet other applications, the uncompensated reference frequency may be combined with the frequency correction value to produced an output reflecting the compensated reference frequency of the XO 220.

The DICXO 210 includes a thermal sensor 230 in close proximity to the XO 220, and a memory 240 for storing data related to the FT response of the XO 220. In one embodiment of the invention, the XO 220, the thermal sensor 230, and the memory 240 may all be configured to communicate separately with the host system 250 via, for example, links 225, 235, or 245 respectively. The host system 250 may comprise several components which themselves may have program applications in communication with the DICXO 210. Additionally, the DICXO 210 may interface with, or itself be a component of, the host system 250. As discussed further below, in one embodiment the XO 220 comprises a SC-cut crystal. Unlike prior approaches in the relevant technology, which have been unsuccessful in implementing TCXOs utilizing SC-cut crystals, the DICXO 210 in effect provides a clock device that takes advantage of the low phase noise and excellent aging characteristics of the SC-cut crystal, without the need for an oven, and enables a host system 250 to compensate for the frequency deviations of the XO 220.

The XO 220 provides the host system 250 with a frequency output 225 (hereinafter “F 225”) representing the uncompensated frequency of the XO 220. As previously mentioned, the XO 220 may be an SC-cut crystal. Compared to an AT-cut crystal, the SC-cut crystal has a lower noise characteristic which reduces the effects of phase noise and of spurious micro-jumps, i.e., random step frequency perturbations of very small magnitude (typically less than 20 ppb). Preferably the XO 220 is manufactured so as to minimize micro-jumps by removing contaminants and loose quartz. SC-cut crystals are generally manufactured to operate on the third overtone mode; however, the system disclosed herein can use an SC-cut crystal operating in any of its resonant frequencies. The XO 220 should be cut to minimize and balance the slope of the FT response over a specified temperature range; in this manner, the temperature sensitivity of the XO 220 remains moderate.

In one embodiment, the thermal sensor 230 determines the ambient temperature in the vicinity of the XO 220 and communicates it to the host system 250 via the communication link 235. In one embodiment, the thermal sensor 230 may comprise a network of thermistors. The configuration of the thermistor network, as well as the number of thermistors included, may be based on the temperature range and frequency resolution required by the components of the host system 250. The data stream 235 may be an analog or a digital signal. For example, in one embodiment an analog-to-digital converter device (e.g., an LTC-2400 SIGMA-DELTA ANALOG TO DIGITAL CONVERTER by LINEAR TECHNOLOGY, not shown) may be coupled to the thermal sensor 230 to convert its analog voltage output to a digital, multi-bit temperature data stream 235.

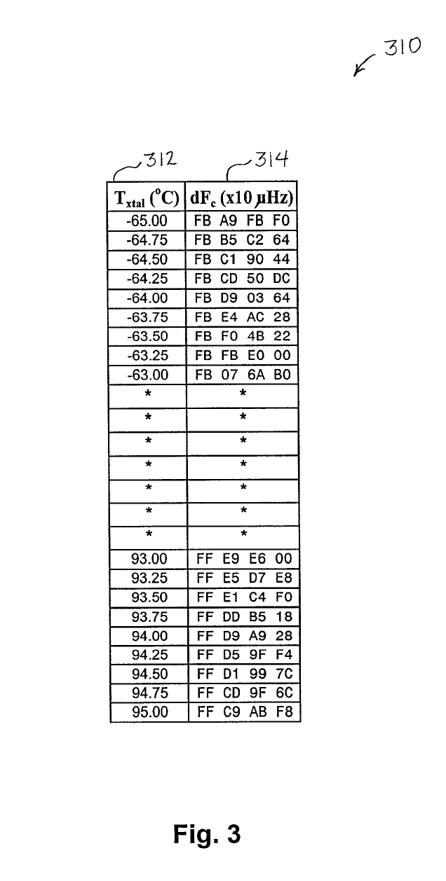

As will be discussed in greater detail below with reference to FIG. 3, the memory 240 stores data related to the uncompensated FT response of the XO 220. The memory 240, which may be a read-only-memory (ROM), may comprise a Dallas DS1624 or DS2420, or a MICRO-CHIP 24AA65, for example. As those of ordinary skill in the relevant technology will recognize, it need not be the case that the memory 240 be incorporated within the DICXO 210, as is shown in FIG. 2. In fact, the contents of the memory 240 may be incorporated as part of the host system 250, for example. In one embodiment, upon powering up, the host system 250 causes the FT data stored in the memory 240 to be downloaded to a local memory store (not shown) in the host system 250.

FIG. 2B is a functional block diagram of an exemplary embodiment of a system for frequency compensation using the DICXO of FIG. 2A. In this embodiment, the XO 220 provides an uncompensated frequency output Fu 225 to an application 252 of the host system 250. The thermal sensor 230 (shown here in thermal contact with the XO 240) provides the application 252 with an input 235 representative of the temperature of the XO 220. The application 252 uses the input 235 and the FT response of the XO 220 data stored in the memory 240 to derive a frequency correction value (ΔF). The application 252 may then combine the uncompensated frequency Fu 225 with the frequency correction value 245 to produce an output Fc 254 representative of the compensated frequency of the XO 220.

In one embodiment, the memory 340 stores the FT response data for the XO 220 in a look-up table having a predetermined frequency correction value for each one of multiple temperature values. FIG. 3 shows a look-up table 310 such as that which may be stored in the memory 340. Tₓₜₐₗ 312 is the temperature (either measured or derived by interpolation) associated with a measured frequency deviation dF_{c} 314 of the XO 220 during the calibration/production process. The frequency deviation dF_{c} 314 is the value representing the difference between the measured, uncompensated frequency F and a specified reference frequency Fᵣ, i.e., dF_{c}=F-Fᵣ. In this example, the frequency deviation dF_{c} 314 is stored with a resolution of 10 μHz, wherein the tabulated values are expressed in two's compliment hexadecimal numbers. Such data points, however, might be converted to different units (e.g., Herz) appropriate for a given application. In one embodiment, Fᵣ is the nominal frequency F₀ of the XO 220. It should be noted, however, that the frequency deviation dF_{c} 314 may be implemented as an absolute value (i.e., an absolute deviation regardless of sign), or even as a value representing the ratio of the frequency deviation to the reference frequency Fᵣ. The specific implementation may take several forms. What is important is that dF_{c} 314 provide an indication of the deviation of the frequency output of the XO 220 from a reference frequency Fᵣ as a function of the temperature of the XO 220.

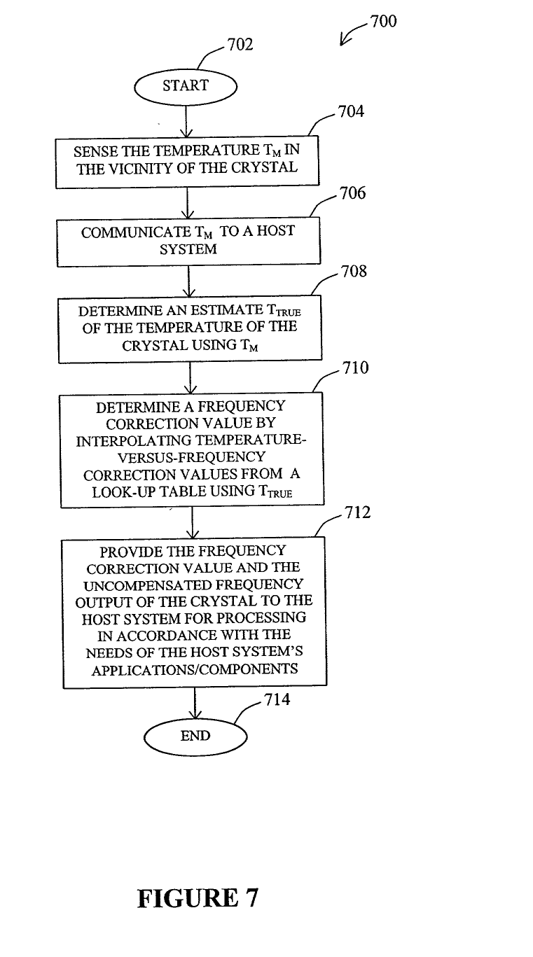

The host system 250 uses the data of the look-up table 310 to determine a frequency correction value by using the estimated temperature Tₜᵣᵤₑ and interpolating the tabulated frequency deviation dF_{c} 314 and temperature values Tₓₜₐₗ 312 for the XO 220. The host system 250 derives Tₜᵣᵤₑ using the temperature data stream 235 provided by the thermal sensor 230, as will be discussed further with reference to FIG. 7. In one embodiment, the look-up table 310 may be associated with a unique crystal (i.e., each DICXO 210 has a unique look-up table calculated for the actual XO 220 included in that DICXO 210).

The look-up table 310 stored in the memory 240 may be generated using the following method. In general terms, the XO 220 is subjected to at least two ambient temperature ramps to measure the FT response of the XO 220. A hysteresis curve 510 (see FIG. 5) representing the FT response of the XO 220 is determined between a first—or low—temperature and a second—or high—temperature, and vice-versa. To obtain the data points, the ambient temperature in the vicinity of the XO 220 is varied at a constant rate from the low temperature to the high temperature, and vice-versa. The frequency deviation value dF_{c} 314 is derived by subtracting the measured frequency of the XO 220 from its nominal frequency Fₒ at each of a number of points in the temperature range.

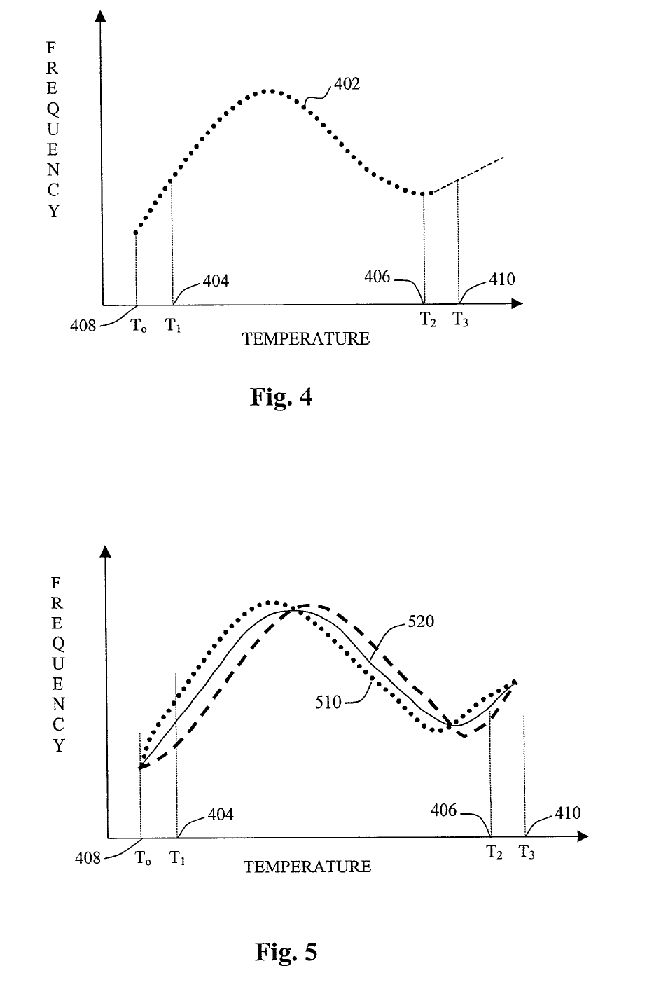

The following discussion provides a more detailed description of the process of deriving the values stored in the look-up table 310 of the memory 240. FIG. 4 shows a graph of the FT response curve 402 for an exemplary XO 220 (e.g., an SC-cut crystal) as its temperature is increased. In one embodiment, the XO 220 is operated from T₁ 404 (about −65° C.) to T₂ 406 (about +95° C.), where the temperature of the XO 220 is increased at a rate of 2°/minute, for example. The frequency output of the XO 220 is measured every 2° C., resulting in a total of 80 data points. An additional number of temperature points, called “overshoots,” (i.e., T₀ 408 and T₃ 410) may be also measured. That is, the FT response of the XO 220 is determined from a low end overshoot temperature T₀ 408 to a high end overshoot temperature T₃ 410. In the previous example, therefore, the XO 220 may be operated over a temperature range from T₀ 408 (about −85° C.) to T₃ 410 (about +115° C.). The XO 220 frequency output is measured every 2° C. for a total of 100 data points (i.e., 80 points from −65° C. to +95° C., plus an additional 10 overshoots at each end). The curve 402 is shown as a dotted line to emphasize frequency measurements are taken at discrete points in the operating temperature range of the XO 220.

To obtain a complete hysteresis curve, the process described above is repeated in the reverse direction (i.e., from the high to the low temperature) to determine the FT response of the XO 220 at a predefined number of temperature points from T₂ 406 to T₁ 404 (or from the high end overshoot temperature T₃ 410 to the low end overshoot temperature T₀ 408), the temperature of the XO 220 again being decreased at a constant rate over time. In the example provided, frequency output of the XO 220 is measured every 2° C. for an additional 100 data points (i.e., 80 points from +95° C. to −65° C., plus a additional 10 overshoots at each end). FIG. 5 shows a resulting hysteresis curve 510 given by plotting all the 200 data points obtained by the above measurements—with the last 100 points described above shown by the dotted line. It should be understood that the overshoots allow for settling to complete the hysteresis curve 510.

The difference between an ideal curve 520 and the hysteresis curve 510 obtained during a temperature ramp is caused by the difference in the temperature between the thermal sensor 230 and the XO 220. This temperature differential arises from the difference in the thermal inertia properties respectively associated with the XO 220 and the thermal sensor 230, which give rise to different time delays in the XO 220 and sensor 230 achieving the same temperature value. The difference in the time delays is defined as the thermal delay t₆₀. Software algorithms, which are well known in the relevant technology, may be used to determine t₆₀ as well as to process the hysteresis curve 510 to create the best-fit (or “ideal”) curve 520. Additionally, these algorithms may interpolate the raw data (i.e., the 200 data points) to fill in the look-up table 310. These data, characterizing the FT response of the XO 220, as well as the t₆₀ of the system may be stored in the memory 240.

In one embodiment, the best-fit curve 520 may be the average value of the legs at each temperature point along the hysteresis curve 510. However, depending on the needs of particular application, a more sophisticated curve fitting technique can be employed. For example, the best-fit curve can take thermal lags into account. That is, the look-up table 310 can include more than one frequency correction value for each temperature point. A first such value may represent the frequency correction that should be applied when the ambient temperature is increasing, while the second should be applied when the ambient temperature is decreasing. The host system 250 may maintain historical temperature information to determine whether the ambient temperature is increasing or decreasing and, from that information, determine which leg of the hysteresis curve 510 should be applied. The data of the best-fit curve 520 is stored in the memory 240. Thus, during operation the memory 240 holds information as to earlier measured frequency-versus-temperature corrections.

It should be understood that frequency stability correction could be limited by the ability of the temperature measuring inertia of the system. Multiple ramp speeds or multiple data points, for example, can increase frequency accuracy. “Look ahead” temperature readings, along with correction components on each leg of the hysteresis curve, can also improve the frequency accuracy to the reference test data.

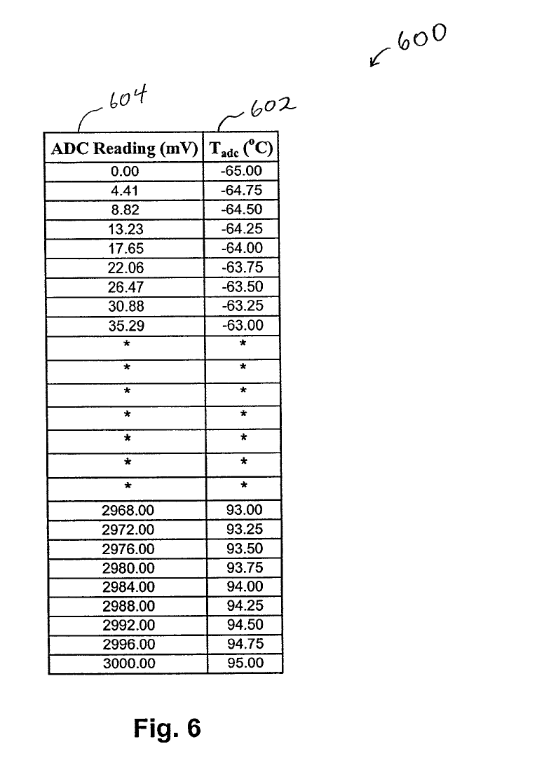

In yet another embodiment of the invention, the memory 240 may also include a second look-up table having data that the host system 250 may use to obtain a more accurate estimate of the temperature Tₜᵣᵤₑ of the XO 220. FIG. 6 shows a look-up table 600 that contains analog-to-digital converter (ADC) voltage readings 604 associated with temperature values T_{ADC} 602. The ADC device, which has already been described with reference to FIG. 2, receives analog voltage signals from the thermal sensor 330 representing the ambient temperature in the vicinity of the XO 220. The ADC device converts the analog voltage input to a digital data voltage reading. The host system 250 then uses the digital voltage reading and the tabulated data of look-up table 600 to obtain by interpolation a more accurate digital estimate of the temperature measured by the thermal sensor 230. Accordingly, the non-linearity of the thermal sensor 230 is accounted for in the interpolation process. As will be further described with reference to FIG. 7, this interpolation process enhances the accuracy of determining the frequency correction value that the host system 250 must apply to the output F 325.

Having described the DICXO 210, its operation in conjunction with the host system 250 will now be described. During operation, ambient temperature fluctuations can subject the XO 220 to large frequency deviations (about 100 ppm, for example) from its nominal frequency F₀ Unlike the other methods and systems (e.g., OCXO, TCXO, and DTCXO) for compensating for the thermally-induced frequency fluctuations of a piezoelectric crystal, the compensation process of the present invention does not require that the XO 220 be subjected to some external condition (e.g., heat to elevate its temperature, or voltage to modulate its resonant frequencies). Instead, the host system 250 indirectly compensates for the frequency fluctuations of the XO 220 by using the data provided by the DICXO 210.

FIG. 7 is a flowchart illustrating a process 700 of using the DICXO 210. The process 700 starts at a state 702 after the DICXO 210 is placed in communication with the host system 250. At a state 704, the thermal sensor 230 periodically senses the ambient temperature in the vicinity of the XO 220. It will be apparent to those of ordinary skill in the art that determining the temperature of the XO 220 may be accomplished in a variety of ways. For example, instead of measuring the ambient temperature in the vicinity of the XO 220, the thermal sensor 230 may be mechanically coupled to the XO 220 to determine more directly the temperature of the XO 220. Such mechanical coupling may be, for example, a heat-conducting adhesive connecting the XO 220 to the thermal sensor 230. Yet another method of determining the temperature of the XO 220 is to use the XO 220 itself; such a method is well known in the relevant technology. Although the sampling rate can be any sampling rate depending on the particular application, in one embodiment the sampling rate may range from about 0.15 seconds to about 0.3 seconds, but is preferably about 0.2 seconds.

The process 700 now proceeds to a state 706 wherein the sensor 230 provides the host system 250 with a data stream 235 indicating the ambient temperature in the vicinity of the XO 220. In one embodiment of the invention, the data stream 235 may be the digital values produced by an ADC converter which has received analog voltage data from the thermal sensor 230. The host system 250 may then use the such digital data in conjunction with the look-up table 600 to derive by interpolation a digital representation T_{M} of the ambient temperature in the vicinity of the XO 220.

The host system 250, at a state 708, then determines an estimate of the temperature T_{TRUE} of the XO 220. T_{TRUE} is given by T_{TRUE}=T_{M}−T_{E}, where T_{E}=(ΔT/Δt)t₆₀ is the temperature error due to the temperature ramp experienced by the XO 220 during operation. The host system 250 determines in real time the values of temperature change (ΔT) over time (Δt), while the value t₆₀ may be retrieved from the memory 240. For illustration purposes, a linear relationship has been used here to determine T_{TRUE} However, it will be apparent to a person of ordinary skill in the relevant technology that determination of T_{TRUE} may, for example, involve the use of historical data of the temperature of the XO 220, wherein such data is processed using a quadratic, cubic, or any higher order, function. Additionally, in some embodiments of the invention T_{TRUE} may be determined using calculus techniques.

The process 700 continues at a state 710 where the host system 250 uses T_{TRUE} along with T_{XTAL} 312 and the frequency correction dF_{c} 314 values of the look-up table 310 to derive by interpolation a frequency correction value. Those of ordinary skill in the relevant technology will recognize that determination of dF_{c} 314 need not be limited to a linear interpolation of the Tₓₜₐₗ 312 and dF_{c} 314 values tabulated in the look-up table 310. For example, the data characterizing the FT response of the XO 220, provided in the memory 240, may be embodied by a mathematical expression modeling the FT response of the XO 220. In one embodiment, an algorithm representing the mathematical model of the FT response of the XO 220 is provided in the memory 240 to the host system 250. Such an algorithm may include, for example, the constants associated with the best-fit curve 520 as well as the form of the expression used (i.e., linear, quadratic, etc.). The host system 250 may then use the algorithm to derive a dF_{c} 314 by providing T_{TRUE} as an input.

Having determined a frequency correction value at state 710, the process 700 now proceeds to a state 712 wherein the host system 250 provides the frequency correction value and the uncompensated frequency F 225 of the XO 220 to its components/applications for further processing in accordance with the needs of those component/applications. In one embodiment, the host system tunes its components by applying the frequency correction value to the uncompensated frequency output F 225 of the XO 220. The compensated frequency F_{c} is the frequency computed by adjusting the uncompensated frequency F by the correction dF_{c} 314 stored in, or derived by interpolation from, the table 310 of the memory 240. More specifically, in one embodiment of the invention the frequency deviation dF_{c} 314 is added to the actual uncompensated DICXO 210 output frequency F 225 to yield the nominal frequency F₀ (e.g., F₀=10 MHz). The compensated frequency F_{c} is valid for the ambient air temperature T_{M} and the uncompensated frequency F 225 measured at the sampling time.

In yet another embodiment of the invention, an application of the host system 250 may use the frequency error correction value dF_{c} 314 to correct for the effects of the FT response of the XO 220. For example, depending on the degree of accuracy desired, a calculation performed by the application may require that the corrected frequency be used instead of the nominal frequency. In some applications, offsetting software signal processing parameters, such as re-tuning numerically controlled oscillators (NCOs) will compensate for the frequency deviation of the XO 220. In one embodiment, the host system 250 may offset an NCO to cancel the effect of the frequency error. The DICXO 210 may be used in a host system 250 that can use an uncompensated frequency 225 when the frequency deviation is provided. Those of ordinary skill in the relevant technology will recognize that there are many ways that a host system 250 may correct, offset, or cancel the frequency error arising from the FT response of an uncompensated XO 220. With the DICXO 210 of the present invention, the correction always occurs outside the DICXO 210 and the correction methods are left to the designers of the host system 250. Having enabled the host system 250 to synchronize the clock generators of its individual components, for example, the process 700 proceeds to a state 714 where it ends. Alternatively, in some embodiments, the process 700 may cycle through the process again, beginning at state 704, in a continuous loop while the host system 250 is in operation.

In view of the above, it will be apparent that by providing a system that produces a reference frequency along with a frequency correction value, which does not utilize the expensive and cumbersome compensation components required by known compensation systems, the DICXO 210 disclosed herein overcomes long standing problems in the industry. The method and system disclosed herein avoids the use of a compensation apparatus that applies an input—other than output loading—to the crystal oscillator in order to modify its output and produce a compensated frequency. The DICXO 210 enables a host system 250 to, for example, tune the clock generator of its individual components by providing a highly accurate frequency correction value for the operating conditions (i.e., temperature and frequency) of the XO 220, without the need for the expensive and cumbersome circuitry and components required by OCXO and TCXO designs.

Those skilled in the relevant technology will appreciate that numerous changes and modifications may be made to the embodiments of the invention described herein, and that such changes and modifications may be made without departing from the spirit of the invention. It is therefore intended that the appended claims cover all such equivalent variations as fall within the true spirit and scope of the invention.

What is claimed is:

1. An apparatus for compensating for thermally based frequency variations in an uncompensated output signal associated with a piezoelectric crystal, the apparatus comprising;
a temperature sensor which identifies a temperature representative of the temperature of the crystal;
a memory which stores frequency correction values associated with the temperature of the crystal;
an application which accesses the memory and retrieves at least one frequency correction value associated with the identified temperature; and
at least one output which provides the uncompensated output signal and the at least one retrieved frequency correction value to a device such that the operation of the device is influenced by the uncompensated output signal and the frequency correction value.

2. The apparatus of claim 1, wherein the application provides to a component a compensated output signal representative of the output signal of the crystal modified by the frequency correction value.

3. The apparatus of claim 2, wherein the act of providing a compensated output signal is performed independently of any influence on the operation of the crystal.

4. A method of compensating for thermally-based frequency variations in a crystal, the method comprising:
storing in a memory frequency correction values associated with frequency-temperature responses of the crystal;
sensing the temperature of the crystal;
retrieving at least one frequency correction value from the memory in response to the temperature of the crystal; and
providing an output signal from the crystal and the retrieved frequency correction value to a system such that operation of at least one component of the system is influenced by said output signal and said frequency correction value.

5. The method of claim 4, wherein the act of providing an output signal and the retrieved frequency correction value comprises:
modifying the frequency of the output signal in response to the frequency correction value to produce a modified output which reflects the frequency correction value; and
providing the modified output to the system.

6. The method of claim 4, wherein the act of storing includes determining a hysteresis curve of the crystal based on frequency-temperature responses of the crystal in a predefined temperature range.

7. The method of claim 6, further comprising computing a best-fit curve of the hysteresis curve.

8. The method of claim 6, further comprising tabulating a frequency correction value associated with the direction of the temperature gradient of the crystal.

9. The method of claim 4, wherein sensing the temperature includes generating a digital signal.

10. The method of claim 4, wherein the frequency correction value is defined by interpolation of the frequency correction values stored in the memory.

11. An apparatus for the management of clock signals used in a host system having at least one component which provides the clock signals to the host system, the apparatus comprising:
a piezoelectric crystal having a frequency-temperature response, wherein during operation an output representative of an uncompensated frequency output of the crystal is communicated to the at least one component;
a thermal sensor which provides an output representative of the temperature of the crystal, wherein said output is communicated to the at least one component; and
a memory which stores a plurality of frequency correction values related to the frequency-temperature response of the crystal, and wherein the memory is accessible to the at least one component for retrieving at least one frequency correction value correlated with said output of the thermal sensor so as to provide clock signals to the host system in response to the output of the crystal and said at least one retrieved frequency correction value.

12. The apparatus of claim 11, wherein the at least one component provides clock signals relating to a compensated frequency in response to the at least one retrieved frequency correction value from the memory and the uncompensated frequency output of the crystal.

13. An apparatus for compensating for thermally based frequency variations in an output of a piezoelectric crystal, the apparatus comprising:
a thermal sensor which provides an output representative of the temperature of the crystal;
a memory which stores a plurality of frequency correction values, wherein the plurality of correction values are associated with frequency-temperature responses of the crystal;
a device responsive to the output of the thermal sensor for selecting at least one frequency correction value from the memory which correlates with said output; and
wherein the device, in response to the output of the crystal and the selected at least one frequency correction value, provides an output comprising a modification of the output of the crystal.

14. The apparatus of claim 13, wherein the thermal sensor comprises a network of thermistors.

15. The apparatus of claim 13, wherein the output representative of the temperature of the crystal is an analog or a digital signal.

16. The apparatus of claim 13, wherein the memory stores at least one table having data correlating a frequency correction value with a temperature of the crystal.

17. The apparatus of claim 13, wherein the memory stores data correlating a frequency correction value with a temperature of the crystal and the temperature gradient of the crystal.

18. The apparatus of claim 13, wherein the memory is located distant from the crystal.

19. The apparatus of claim 13, wherein the device derives a frequency correction value by interpolation of the frequency correction values stored in the memory.

20. The apparatus of claim 13, wherein the device produces a modified output of the crystal independent of any influence, other than output loading, on the crystal itself.

21. The apparatus of claim 13, wherein the apparatus provides an output signal which comprises a modification of the output of the crystal, wherein the modification correlates to thermally-based frequency variations in said crystal, and wherein the apparatus functions independently of any influence on the operation of the crystal.

22. A method of compensating for thermally based frequency variations in an output signal associated with a piezoelectric crystal, the method comprising;
identifying a temperature representative of the temperature of the crystal;
producing a frequency correction value in response to the identified temperature; and
providing the output signal and the frequency correction value to a system such that a component of the system functions in a manner which is influenced by the frequency correction value.

23. The method of claim 22, wherein the act of providing the output signal and the frequency correction value comprises providing a compensated output signal representative of the output signal of the crystal modified by the frequency correction value.

24. The method of claim 23, wherein the act of providing a compensated output signal is performed independently of any influence on the operation of the crystal.

25. An apparatus for compensating for thermally based frequency variations in an output signal associated with a piezoelectric crystal, the apparatus comprising:
means for identifying a temperature representative of the temperature of the crystal;
means for producing a frequency correction value in response to the identified temperature; and
means for providing the output signal and the frequency correction value to a system such that a component of the system functions in a manner which is influenced by the frequency correction value.

26. The apparatus of claim 25, wherein the means for providing the output signal and the frequency correction value comprises means for providing a compensated output signal representative of the output signal of the crystal modified by the frequency correction value.

27. The apparatus of claim 26, wherein the means for providing a compensated output functions independently of any influence on the operation of the crystal.

28. A method of compensating for variations in output from a piezoelectric crystal which is provided to a host system, the method comprising:
identifying output characteristics of the crystal in selected operating conditions; and
modifying an output of the crystal independently from influencing operation of the crystal, using at least one of the identified output characteristics, to compensate for the influence of selected operating conditions on said output.

29. The method of claim 28, wherein the act of modifying comprises:
providing a frequency correction value reflecting output characteristics of the crystal; and
modifying the output of the crystal in response to the frequency correction value.

30. The method of claim 29, wherein providing a frequency correction value comprises executing an algorithm which defines the frequency correction value.

31. The method of claim 29, wherein providing a frequency correction value comprises selecting at least one value from a database reflecting output characteristics in view of selected operating conditions of the crystal.

32. A method of providing frequency compensation data to a device, including a reference frequency supplied by a crystal, the reference frequency of the crystal deviating from a nominal frequency of the crystal as a function of the temperature of the crystal, the method comprising:
storing in a memory a characterization of the deviation of the frequency of the crystal from a nominal value, wherein the value of the deviation is a function of the value of the temperature of the crystal;
providing to the device a signal reflecting the temperature of the crystal;
providing to the device a signal reflecting the uncompensated frequency of the crystal; and
providing memory access to the device for communication to said device of at least a part of the characterization stored in the memory.

33. A system for providing a frequency correction value associated with thermally-based frequency deviations of a crystal, the system comprising:
a crystal which produces an uncompensated frequency output;
a thermal sensor which provides a signal reflective of the temperature of the crystal;
a memory which stores data characterizing the frequency-versus-temperature responses of the crystal; and
a device, responsive to the signal from the thermal sensor and the data stored in the memory, for providing a frequency correction value associated with the uncompensated frequency output of the crystal.

34. The system of claim 33, wherein the data comprises a model of the frequency-versus-temperature responses of the crystal.

35. The system of claim 34, wherein the model comprises a software algorithm.

36. The system of claim 33, wherein the memory comprises a portable memory device, and wherein the data stored in the memory comprises an algorithm used to derive a frequency correction value in response to the temperature of the crystal.
